(19) United States
(12) Patent Application Publication
(10) Pub. No.: US 2010/0294342 A1
(43) Pub. Date: Nov. 25, 2010

(54) SOLAR CELL MODULE AND ELECTRONICS DEVICE INCLUDING THE SOLAR CELL MODULE

(76) Inventors: Hiroyuki Nakanishi, Osaka-shi (JP); Kohji Miyata, Osaka-shi (JP); Yoshihide Iwazaki, Osaka-shi (JP); Seiji Ishihara, Osaka-shi (JP); Masato Yokobayashi, Osaka-shi (JP); Etsuko Ishizuka, Osaka-shi (JP); Kiyoharu Shimano, Osaka-shi (JP); Katsunobu Mori, Osaka-shi (JP)

Correspondence Address: NIXON & VANDERHYE, PC, 901 NORTH GLEBE ROAD, 11TH FLOOR, ARLINGTON, VA, 22203, US

(21) Appl. No.: 12/783,859

(22) Filed: May 20, 2010

(30) Foreign Application Priority Data
May 25, 2009 (JP) 2009-125733

(51) Int. Cl. H01L 31/048; H01L 31/18

(52) U.S. Cl. 136/251; 438/64; 257/E31.11

(57) ABSTRACT

A solar cell module 1 includes a plurality of solar cells 30. Each of the plurality of solar cells 30 is disposed on a corresponding one of a plurality of pad sections in such a manner that the each of the plurality of solar cells 30 is electrically connected to the corresponding one of the plurality of pad sections. The each of the plurality of solar cells 30 is electrically connected to a corresponding inner lead section 120. A cathode section 114 and an anode section 116 feed an electric current generated by the plurality of solar cells 30. A metal lead frame is provided such that the plurality of pad sections, the inner lead sections 120, the cathode section 114 and the anode section 116 are provided therein as a part of the lead frame itself. This configuration enables the solar cell module 1 to endure against bending stress and to be curved. As a result, it is possible to provide a solar cell module which can be disposed along a curved surface of an electronics device.

This Nonprovisional application claims priority under 35 U.S.C. §119(a) on Patent Application No. 2009-125733 filed in Japan on May 25, 2009, the entire contents of which are hereby incorporated by reference.

### TECHNICAL FIELD

The present invention relates to a type of portable electronics device, and a power generator which is included in the portable electronics device and which functions as an energy source for the portable electronics device.

### BACKGROUND ART

Significance of a portable electronics device such as a mobile phone has recently increased as a commodity for daily life. The portable electronics device generally operates with a secondary cell, such as a lithium cell, as a power source. The secondary cell is charged by receiving electric power from an external power source such as an outlet. An amount of charge of the portable electronics device decreases while being used or toted, and it is often difficult to acquire a power source for charging the portable electronics device.

For increasing the amount of charge, a device for charging the portable electronics device by a dry cell, or another secondary cell in which electric power generated by a solar cell device is stored, may be used. Fortunately, such a charging device does not require the external power source. However, the charging device requires to be toted with the portable electronics device and to be connected to the portable electronics device so as to charge the portable electronics device. This causes an inconvenience to handle the charging device while traveling. For this reason, it is desired that the portable electronics device include the solar cell device.

The solar cell device converts solar energy, such as sunlight, into electric energy. The solar cell device is mainly used as a secondary power source for charging a storage cell or as a primary power source for a device which requires a power source. The solar cell device which has been recently used is generally for household use.

Generally, in a solar cell module, solar cells that are connected with each other in series or in parallel via interconnectors are sealed in transparent resin. Some solar cell modules are fitted in frames made from aluminum or the like or in plastic vessels. Unfortunately, such a conventional solar cell module is heavy for securing mechanical strength thereof.

To solve the problem, a method of further decreasing the solar cell module in weight is proposed. Patent Literature 1 is disclosed for attaining decrease in weight and sufficient mechanical strength of the solar cell module. In a technique of Patent Literature 1, the decrease in weight is realized by arranging the solar cell module to have an outer shape made only from photic plastic resin. Further, the mechanical strength is enhanced by providing a frame so as to surround the solar cell module.

### CITATION LIST

Patent Literature 1

Japanese Patent Application Publication, Tokukaihei, No. 9-51117 A (Publication Date: Feb. 18, 1997)

### SUMMARY OF THE INVENTION

### Technical Problem

Decrease in weight and size will be required as various electronics devices become portable. On this account, a solar cell device included in a portable electronics device also will be required to decrease in weight and size.

As described above, the solar cell device which has been recently used is generally for household use. Therefore, even if the technique of Patent Literature 1 realizes the decrease of the solar cell device in size so that the solar cell device becomes applicable to the portable electronics device, the technique causes problems, such as a decrease in strength, an increase in weight, poor appearance or an increase in cost. Further, if a conventional solar cell module is provided along a curved surface of an electronics device, strong stress that is put on a substrate of the solar cell module would break the solar cell module.

Furthermore, the portable electronics device should be usable under severe environments for the electronics device, such as exposure to the sun, high temperature, high humidity, pressure on the portable electronics device, or drop of the portable electronics device while toted. Therefore, the solar cell device which can endure under these external environments is required.

The present invention is made in view of the problems, and an object of the present invention is to provide a solar cell module which can be provided along a curved surface of an electronics device and which has sufficient mechanical strength, a method for producing the solar cell module, and an electronics device including the solar cell module.

### Solution to Problem

In order to attain the object, a solar cell module of the present invention includes a plurality of solar cells, and comprises: a plurality of pad sections on each of which a corresponding one of the plurality of solar cells is provided such that the each of the plurality of pad sections is electrically connected to a first polar surface of the corresponding one of the plurality of solar cells; at least one inner lead section that is electrically connected to a second polar surface of at least one of the plurality of solar cells, the second polar surface having a polarity different from the first polar surface; a cathode section and an anode section, from which an electric current generated by each of the plurality of solar cells is fed; a lead frame made from a metal, in which lead frame the plurality of pad sections, the at least one inner lead section, the cathode section and the anode section are provided as a part of the lead frame itself; an insulating layer provided on a side of the lead frame which is opposite to another side of the lead frame on which the plurality of solar cells are provided; and a sealing layer for sealing at least the plurality of solar cells, the anode section and the cathode section.

According to the configuration, the solar cell module of the present invention includes the plurality of solar cells, the lead frame, the insulating layer and the sealing layer. The lead frame made from a metal is used as a substrate on which the solar cells are to be provided. In the lead frame, the pad sections, the inner lead section, and the cathode and anode sections are provided as a part of the lead frame itself.

A respective of the plurality of solar cells are fixed to the respective pad sections and electrically connected to the inner lead section. The plurality of solar cells are connected with each other via the inner lead section to which the respective of the plurality of solar cells are electrically connected. A cathode of the solar cells connected with each other is provided as a cathode section in the lead frame. Similarly, an anode of the solar cells connected with each other is provided as an anode section in the lead frame. The cathode and anode sections feed electric power generated by the plurality of solar cells.

The sealing layer is provided on a surface of the lead frame on which surface the solar cells are provided so that the sealing layer seals the solar cells, the cathode and anode sections. Meanwhile, the insulating layer is provided on another surface of the lead frame which surface is opposite to the surface where the solar cells are provided.

As described above, the solar cell module of the present invention does not use an interconnector which is conventionally used for connecting the solar cells with each other. This makes it possible to reduce a total thickness of the solar cell module as compared to a conventional solar cell module. Further, the sealing layer covers an upper surface of the lead frame and the insulating layer covers a lower surface of the lead frame, thereby reinforcing the solar cell module.

Furthermore, the metal lead frame is used in the solar cell module of the present invention. This enables the solar cell module to endure against bending stress. Therefore, the solar cell module of the present invention can be curved. As a result, if a surface of an electronics device on which the solar cell module is to be provided is curved, the solar cell module can be provided on the surface without being broken.

As described above, the solar cell module of the present invention is thin and has sufficient mechanical strength even if the solar cell module is curved.

In order to attain the object, a solar cell module of the present invention includes a plurality of solar cells, and comprises: a plurality of pad sections on each of which a corresponding one of the plurality of solar cells is provided; at least one inner lead section that is electrically connected, via a metal wire, to the corresponding one of the plurality of solar cells; a lead frame made from a metal which lead frame includes at least the plurality of pad sections and the at least one inner lead section; an insulating layer provided on a side of the lead frame which is opposite to another side of the lead frame on which the plurality of solar cells are provided; and a sealing layer for sealing the plurality of solar cells and the metal wire, the solar cell module being capable of being disposed on a housing of an electronics device with the solar cell module curved.

The configuration makes it possible to provide a solar cell module which can be provided in a housing of an electronics device with the solar cell module curved.

In order to attain the object, a method for producing a solar cell module of the present invention is a method for producing a solar cell module including a plurality of solar cells, and comprises the steps of: preparing a lead frame made from a metal by forming, in the lead frame, a plurality of pad sections, an inner lead section, an anode section and a cathode section as a part of the lead frame itself; disposing a conductive material having a thermosetting property on each of the plurality of pad sections; disposing a corresponding one of the plurality of solar cells on the each of the plurality of pad sections on which the conductive material is disposed, the corresponding one of the plurality of solar cells being disposed in such a manner that a first polar surface of the corresponding one of the plurality of the solar cells faces the each of the plurality of pad sections; hardening the conductive material by heating the lead frame on which the plurality of solar cells are disposed; connecting a second polar surface of each of the plurality of solar cells to the inner lead section via a metal wire, the second polar surface having a polarity different from the first polar surface; forming an insulating layer provided on a side of the lead frame which is opposite to another side of the lead frame on which the plurality of solar cells are provided; and forming a sealing layer so as to seal at least the plurality of solar cells, the anode section and the cathode section.

The configuration makes it possible to produce a solar cell module which can be used in an curved state and provided in a portable electronics device.

Further, in order to attain the object, an electronics device of the present invention includes any one of the foregoing solar cell modules.

The configuration makes it possible to provide an electronics device in which a solar cell module can be provided in a curved state.

For a fuller understanding of the nature and advantages of the invention, reference should be made to the ensuing detailed description taken in conjunction with the accompanying drawings.

### Advantageous Effects of Invention

In a solar cell module of the present invention, with the use of a lead frame as a substrate on which solar cells are to be provided, it is possible to connect a plurality of solar cells with each other. In the configuration, the solar cells are connected with each other without using a conventional interconnector, thereby resulting in that a thin solar cell module can be attained. Further, an upper surface of the lead frame is ultimately covered with transparent resin and a lower surface of the lead frame is ultimately covered with an insulating sheet, thereby reinforcing the solar cell module. Consequently, the solar cell module in accordance with the present invention is thin and has sufficient mechanical strength, thereby resulting in that the solar cell module can be provided in a portable electronics device.

Further, provision of a bendable portion between adjacent solar cells allows the solar cell module of the present invention to be disposed in a curved housing.

### BRIEF DESCRIPTION OF DRAWINGS

FIG. 1

FIG. 1 is a perspective view of a whole solar cell module in accordance with an embodiment of the present invention.

FIG. 2

(a) of FIG. 2 shows an upper surface of a solar cell module in accordance with an embodiment of the present invention, and (b) of FIG. 2 is a cross-sectional view of a solar cell module in accordance with an embodiment of the present invention.

FIG. 3

FIG. 3 shows a process of applying silver paste to pad sections of a lead frame in accordance with an embodiment of the present invention.

FIG. 4

FIG. 4 shows a process of disposing solar cells on pad sections of a lead frame in accordance with an embodiment of the present invention.

FIG. 5

FIG. 5 shows a process of connecting solar cells to inner leads of a lead frame in accordance with an embodiment of the present invention.

FIG. 6

FIG. 6 shows a process of covering, with transparent resin, a lead frame in accordance with an embodiment of the present invention.

FIG. 7

(a) of FIG. 7 is a perspective view of a whole solar cell, and (b) of FIG. 7 is a cross-sectional view of a solar cell.

FIG. 8

FIG. 8 shows an electric circuit of a solar cell module in accordance with an embodiment of the present invention.

FIG. 9

FIG. 9 shows an upper surface of a lead frame in accordance with an embodiment of the present invention.

FIG. 10

FIG. 10 is a perspective view illustrating upper and lower surfaces when a left half of a lead frame in accordance with an embodiment of the present invention is viewed in a double-spread manner.

FIG. 11

FIG. 11 is a perspective view of a whole solar cell module in accordance with an embodiment of the present invention.

FIG. 12

(a) of FIG. 12 shows an upper surface of a solar cell module in accordance with an embodiment of the present invention, and (b) of FIG. 12 is a cross-sectional view of a solar cell module in accordance with an embodiment of the present invention.

FIG. 13

FIG. 13 shows an upper surface of a lead frame in accordance with an embodiment of the present invention.

FIG. 14

FIG. 14 shows an upper surface of a lead frame in accordance with an embodiment of the present invention.

FIG. 15

FIG. 15 shows an upper surface of a lead frame in accordance with an embodiment of the present invention.

FIG. 16

FIG. 16 shows an electric circuit of a solar cell module in accordance with an embodiment of the present invention.

FIG. 17

FIG. 17 shows an upper surface of a solar cell module in accordance with an embodiment of the present invention.

FIG. 18

FIG. 18 shows an upper surface of a lead frame in accordance with an embodiment of the present invention.

FIG. 19

FIG. 19 is a cross-sectional view of a solar cell module in accordance with an embodiment of the present invention which solar cell module is in a curved state.

FIG. 20

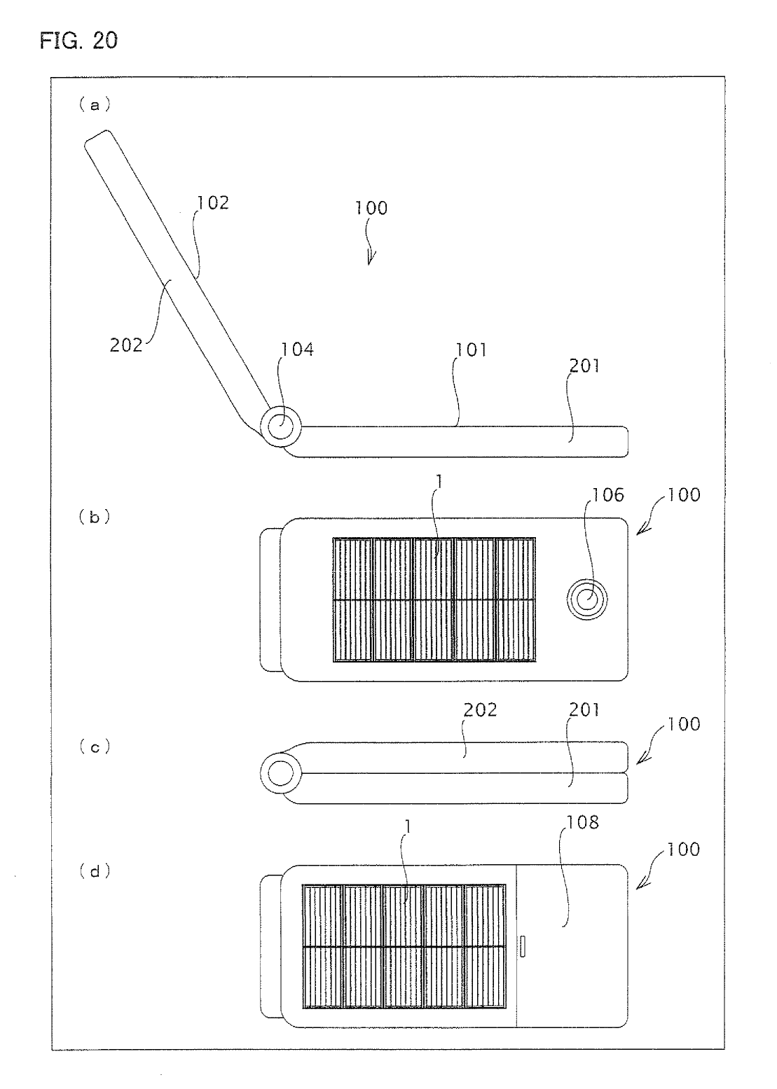

(a) of FIG. 20 shows a side of a flip phone in an open state, which flip phone includes a solar cell module in accordance with an embodiment of the present invention. (b) of FIG. 20 shows an upper surface of a flip phone in a closed state, which flip phone includes a solar cell module in accordance with an embodiment of the present invention. (c) of FIG. 20 shows a side of a flip phone in a closed state, which flip phone includes a solar cell module in accordance with an embodiment of the present invention. (d) of FIG. 20 shows a lower surface of a flip phone in a closed state, which flip phone includes a solar cell module in accordance with an embodiment of the present invention.

### DESCRIPTION OF EMBODIMENTS

The following describes an embodiment of the present invention in detail with reference to drawings.

### First Embodiment

(Outline of Solar Cell Module 1)

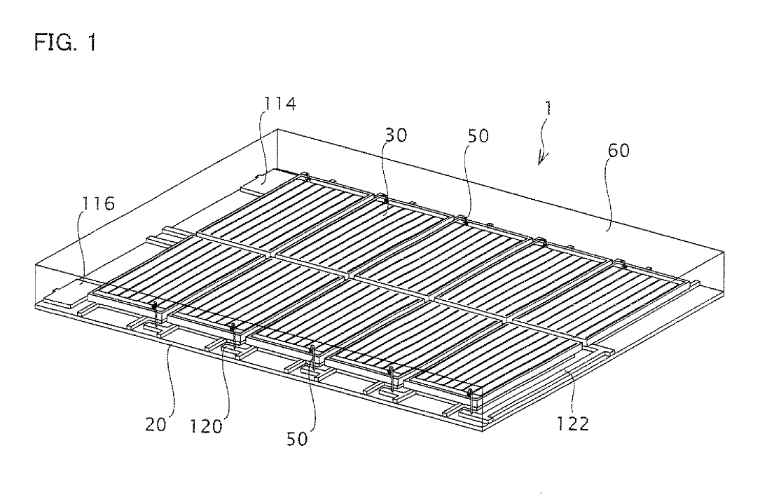

The following describes an outline of a solar cell module 1 in accordance with a first embodiment of the present invention with reference to FIG. 1.

FIG. 1 is a perspective view of a whole solar cell module 1 in accordance with the present embodiment. As shown in FIG. 1, the solar cell module 1 includes a lead frame 10, an insulating sheet 20, solar cells 30, a conductive material, gold wires 50 and transparent resin 60. These components are described later. The lead frame 10 is used as a substrate on which the solar cells 30 are to be provided. The lead frame 10 is patterned to have pad sections 112, a cathode section 114, an anode section 116, support bars 118, inner lead sections 120 and a coupling section 122.

The respective solar cells 30 are fixed, by the conductive material, to the respective pad sections 112 provided in the lead frame 10. The respective solar cells 30 are connected to the respective inner lead sections 120 provided in the lead frame 10 via the respective gold wires 50. The plurality of solar cells 30 are electrically connected with each other via the conductive material, the gold wires 50 and the coupling section 122. The plurality of solar cells 30 can be arranged such that (i) all of them are connected with each other in series or in parallel, (ii) sets of the solar cells 30 that are connected in parallel with each other are connected in series with each other, or (iii) sets of the solar cells 30 that are connected in series with each other are connected in parallel with each other. The following describes the first embodiment in which all of the plurality of solar cells 30 are connected in series with each other.

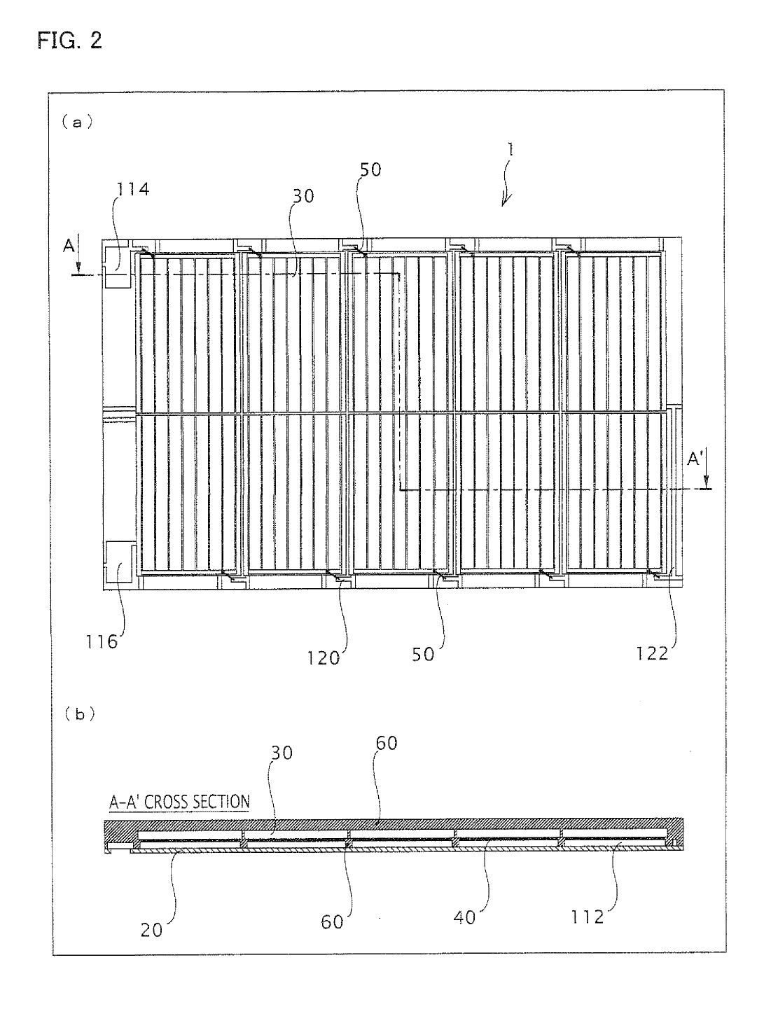

(a) of FIG. 2 shows an upper surface of the solar cell module 1 in accordance with the present embodiment. As shown in (a) of FIG. 2, a cathode of the solar cells 30 that are connected with each other is provided as the cathode section 114 in the lead frame 10. Similarly, an anode of the solar cells 30 is provided as the anode section 116 in the lead frame 10. The cathode section 114 and the anode section 116 are exposed to an outside of the lead frame 10 so that electric power generated by the solar cells 30 can be fed to an external section.

(b) of FIG. 2 is a cross-sectional view taken along line A-A′ shown in (a) of FIG. 2. A sealing layer is provided on the upper surface of the lead frame 10 so as to seal the solar cells 30, the cathode and anode sections. That is, as shown in (b) of FIG. 2, the transparent resin 60 is provided as the sealing layer. Further, an insulating layer is provided on the lower surface of the lead frame 10, and the insulating sheet 20 is provided as the insulating layer.

(Manufacturing Process of Solar Cell Module 1)

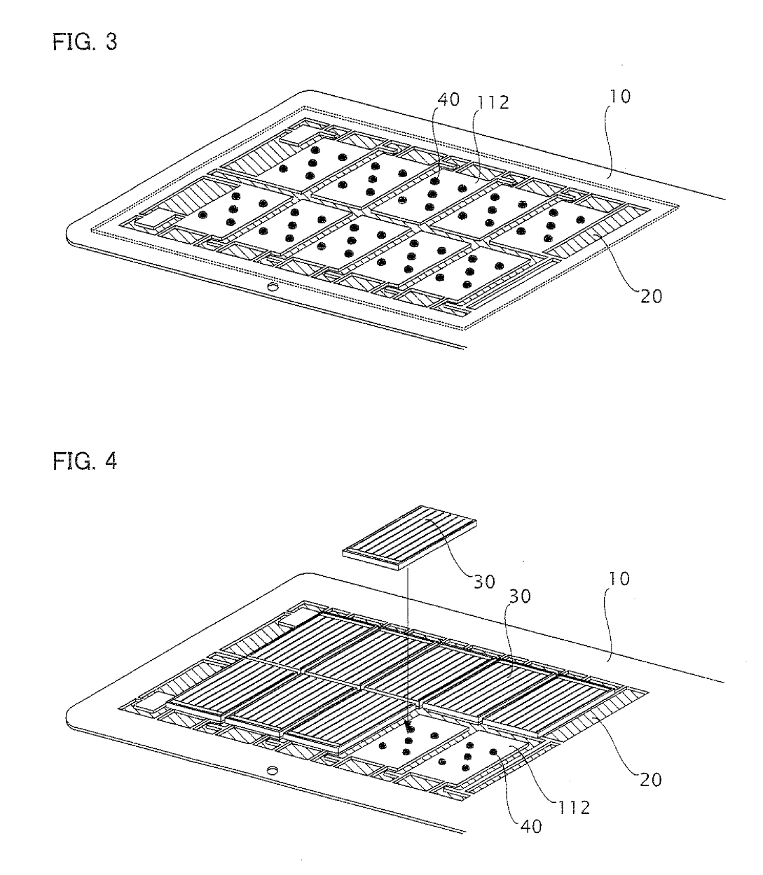

The following describes a manufacturing process of the solar cell module 1 with reference to FIGS. 3 to 6.

Firstly, the conductive material is applied to the pad sections 112. In the present embodiment, silver paste 40 is used as the conductive material. FIG. 3 shows a process of applying the silver paste 40 to the pad sections 112. As shown in FIG. 3, the silver paste 40 is applied to the pad sections 112. More specifically, the application of the silver paste 40 is performed with the use of a dispenser in such a manner that the silver paste 40 is applied from a needle having a through-hole at an end of the needle. The silver paste 40 is mainly made by mixing flaky silver with a chemical product such as powdery epoxy resin and has a thermosetting property. In FIG. 3, five spots of the silver paste 40 exist on each of the pad sections 112. However, the number of spots of the silver paste 40 on the each of the pad sections 112 is adjusted as appropriate in accordance with a size of a pad section 112 and an application quantity per spot.

FIG. 4 shows a process of fixing the solar cells 30 to the pad sections 112. As shown in FIG. 4, each of the solar cells 30 is disposed on a corresponding pad section 112 by use of a die bonder in such a manner that the corresponding pad section 112 is pressed so that the applied silver paste 40 is spread over the corresponding pad section 112. At this time, the application quantity of the silver paste 40 is adjusted so as not to protrude too much from the corresponding pad section 112. Then, the entire lead frame 10 is heated at 150° C. for an hour by use of a baking device so that the silver paste 40 is hardened. As such, the solar cells 30 are surely fixed to the pad sections 112 by the heating process.

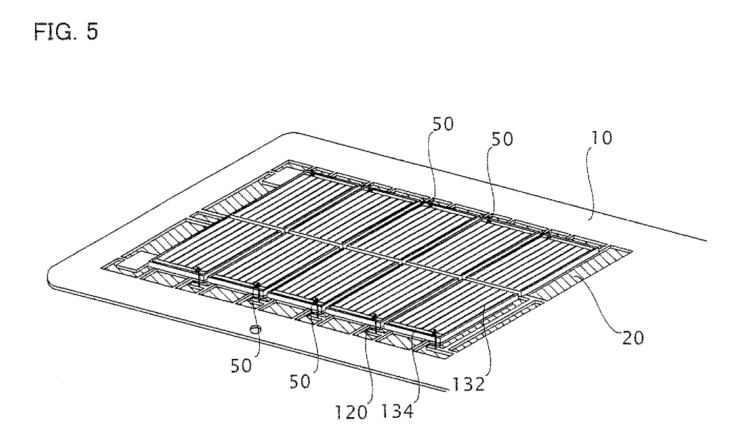

FIG. 5 shows a process of connecting a portion 134 that collectively includes power collectors 132, to a corresponding inner lead 120 via a gold wire 50. As shown in FIG. 5, the power collectors 132 (power collector-cum-cathode sections) are provided on top of each of the solar cells 30 so as to form the portion 134 that collectively includes the power collectors 132. The portion 134 that collectively includes the power collectors 132 is then connected to the corresponding inner lead section 120 via the gold wire 50. The connection of the portion 134 to the corresponding inner lead section 120 is performed by use of a wire bonder. Obtained connection portions are in such a state that (i) gold is connected to gold, (ii) silver is connected to gold or (iii) tin is connected to gold, and therefore the connection portions stabilize. Further, use of the gold wire 50 reduces electric resistance between the solar cell 30 and the inner lead 120. In the present embodiment, the solar cell 30 is connected to the inner lead 120 via one gold wire 50, but, the solar cell 30 may be connected to the inner lead 120 via two or more gold wires 50 so that risk of open faults caused by breaking of the wire is reduced.

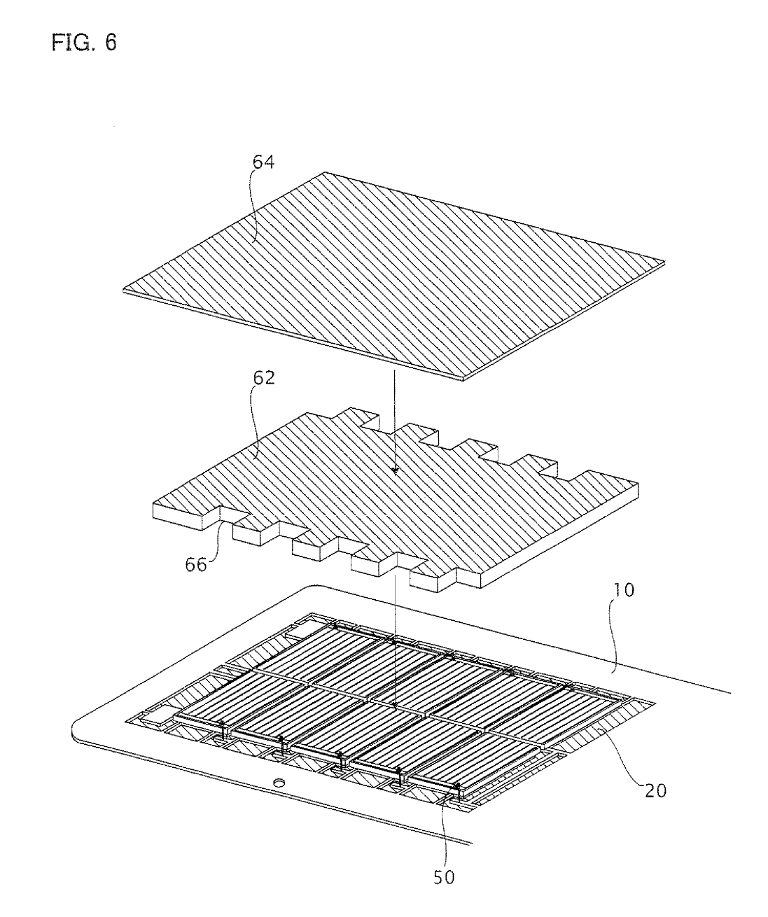

FIG. 6 shows a process of covering the lead frame 10 with a sheet 62 and a sheet 64. As shown in FIG. 6, the sheet 62 made from EVA (ethylene vinyl acetate) is put on the solar cells 30, and then the sheet 64 made from PET (polyethylene terephthalate) is also put on the sheet 62. The sheets 62 and 64 are heated at 135° C. under pressure. The sheet 62 is 38×65×0.6 mm in size and the sheet 64 is 40×67×0.08 mm in size.

The sheet 62 has dent portions 66 so as not to make contact with the gold wires 50 in putting the sheet 62 on the solar cells 30. The sheet 62 is spread over the solar cells 30 by being heated under pressure so as to fit uneven portions with which a lower surface of the sheet 62 makes contact. As a result, the sheet 62 spreads up to approximately 44×71×0.25 mm in size, thereby perfectly sealing vicinity of the gold wires 50.

The sheet 64 functions to prevent the sheet 62 from making contact with a tool in being pressed and to secure flatness of a surface of the solar cell module 1. Further, the insulating sheet 20 attached to a side of the solar panels 30 which is opposite to another side of the solar panels 30 where the sheet 64 is attached prevents the sheet 64 from leaking toward the insulating sheet 20.

A laminated body of the sheets 62 and 64 constitutes the transparent resin 60. The transparent resin 60 may be made from the epoxy resin or the EVA.

Lastly, a cradle section 110 is cut off or punched out by a cutter or a puncher. Thus, a substantially cuboid solar cell module 1 as shown in FIG. 1 is produced. The solar cell module 1 thus produced is 40×67×0.85 mm in size.

(Structure of Solar Cell 30)

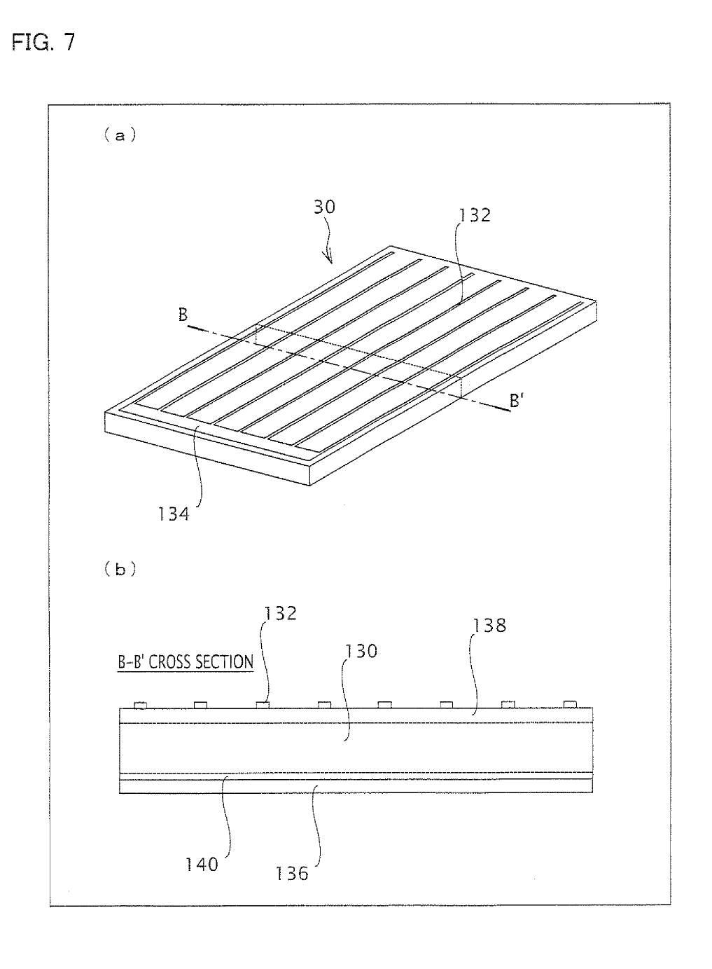

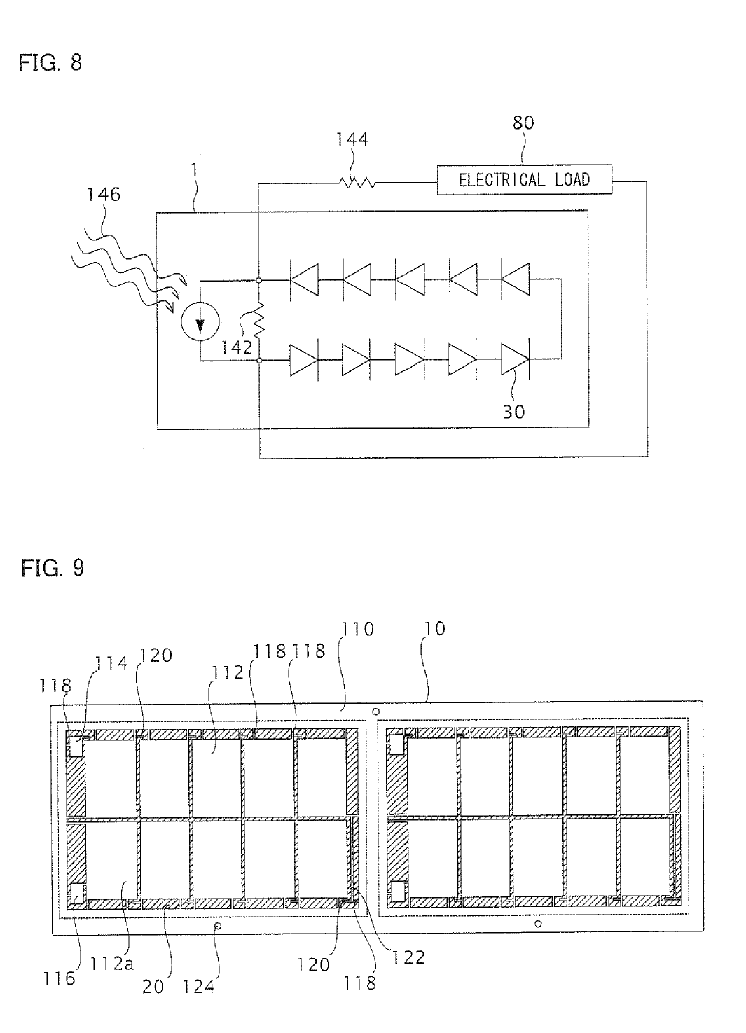

The following describes a solar cell 30 included in the solar cell module 1 in detail with reference to FIGS. 7 and 8.

The solar cell 30 is made in such a manner that a flat plate cut out from a polycrystalline silicone ingot is processed and then the processed plate is divided into individual pieces. For example, the flat plate is 156×156 mm in size, and an individual solar cell 30 is 12×18×0.2 mm in size. In this case, the number of the solar cells 30 cut out from a single flat plate is 12×8 (i.e., 96).

A top portion of the solar cell 30 serves as a cathode section, and a bottom portion of the solar cell 30 serves as an anode section. (a) of FIG. 7 is a perspective view showing a structure of the solar cell 30. As shown in (a) of FIG. 7, the top portion (cathode section) mainly includes power collectors 132 made from sintered silver, that is, a portion 134 that collectively includes the power collectors 132. The bottom portion (anode section) mainly includes an aluminum layer 136 made from sintered aluminum.

(b) of FIG. 7 is a cross-sectional view taken along line B-B′ shown in (a) of FIG. 7. As shown in (b) of FIG. 7, an N⁺ layer 138, a P⁻ layer 130 and a P⁺ layer 140 are provided between the top and bottom portions of the solar cell 30 in this order from the top portion.

(Mechanism of Power Generation of Solar Cell 30)

The following describes a mechanism of power generation of the solar cell 30 in detail with reference to FIG. 8.

FIG. 8 shows an electric circuit of the solar cell module 1. As shown in FIG. 8, the solar cell module 1 is arranged such that ten solar cells 30, each of which is a pn junction diode, are connected to a photovoltaic current source in inverse parallel. A reference sign 142 shown in FIG. 8 indicates leakage current equivalent resistance, and a reference sign 144 indicates series resistance. When the solar cells 30 are irradiated with light 146 such as sunlight, solar energy is converted into electric energy by photovoltaic effect of the solar cells 30. The electric energy flows as a short-circuit current (Isc) and is output to a cell 80 which is an electrical load. In this way, the solar cell module 1 generates electric power. If the solar cell module 1 is not connected to the cell 80, all photovoltaic power is consumed in the solar cells 30 and therefore is clamped at a forward voltage of the solar cell 30. The voltage at this time is an open-circuit voltage (Voc) of the solar cell module 1.

(Structure of Lead Frame 10)

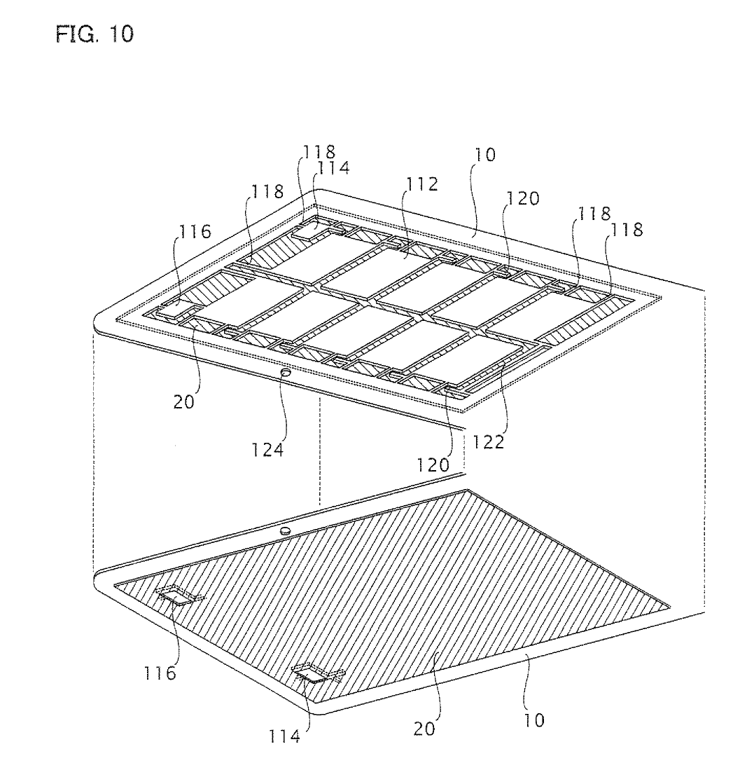

The following describes the lead frame 10 including the solar cells 30 in detail with reference to FIGS. 9 and 10.

FIG. 9 shows an upper surface of the lead frame 10 in accordance with the present embodiment. The lead frame 10 is 54×150×0.15 mm in size. As described above, as shown in FIG. 9, the lead frame 10 is patterned to have the cradle section 110, the pad sections 112, the cathode section 114, the anode section 116, the support bars 118, the inner lead sections 120 and the coupling section 122. The cradle section 110 is an outer frame of the lead frame 10 and has holes 124. The holes 124 are for putting pins into the holes 124 so as to place the lead frame 10 at a right position in the manufacturing process. The pad sections 112 are sections onto which the solar cells 30 are to be fixed, and each of the pad sections 112 is 11.5×17.5 mm in size. Each of the cathode section 114 and the anode section 116 is 3×6 mm in size. Each of the support bars 118 connects each of these sections to the cradle section 110. Top surfaces of the inner lead sections 120 are coated with gold, silver or tin, and the inner lead sections 120 are connected to the solar cells 30 via the gold wires 50. The coupling section 122 connects the pad sections 112 provided in an upper area of the lead frame 10 to the inner lead sections provided in a lower area of the lead frame 10. All of the components thus provided in the lead frame 10 are formed by chemical etching or physical punching.

It can be considered that the surface of the lead frame 10 is colored by various colors, and the colored surface is viewed from the upper surface of the solar cell module 1. In the present embodiment, because the pad sections 112 are smaller in size than the solar cells 30, the pad sections 112 are totally covered with the solar cells 30. Therefore, the color of the lead frame 10 is not viewed from the upper surface of the solar cell module 1. However, appearance may be put great importance on in combination of the color of the solar cells 30 with the color of the lead frame 10 in the final stage of manufacture of the solar cell module 1. In view of this, the color of the lead frame 10 may be viewed from the upper surface of the solar cell module 1.

FIG. 10 is a perspective view illustrating upper and lower surfaces when a left half of the lead frame 10 is viewed in a double-spread manner. As shown in FIG. 10, the insulating sheet 20 which is 44×71×0.15 mm in size is attached to the lower surface of the lead frame 10 by an insulating adhesive. The cathode section 114 and the anode section 116 are exposed from the insulating sheet 20. A pad section 112a adjacent to the anode section 116 is connected to the anode section 116 within the lead frame 10 and has the same electric potential as that of the anode section 116. In view of this, the pad section 112a itself may be used as a terminal of an anode section by exposing the pad section 112a from the insulating sheet 20. The insulating sheet 20 is made from an insulating material of PET or the like having heat resistance. In a case where higher heat resistance is required, polyimide or the like material may be used. If a colored insulating material is used as the insulating sheet 20, the color of the colored insulating material is viewed in the vicinity of the solar cells 30 through the transparent resin 60. As described above, such an insulating sheet 20 may be used from the viewpoint of the appearance of the solar cell module 1.

The lead frame 10 is made from a metal having malleability. The metal encompasses a metal alloy. In the present embodiment, the lead frame 10 is made from an alloy (42 alloy or copper alloy). The 42 alloy includes 42% of nickel, and mainly includes iron except for nickel. Further, the copper alloy mainly includes copper. Use of the lead frame 10 made from the metal enables the solar cell module 1 to endure against bending stress, thereby allowing the solar cell module 1 to be disposed in a curved state along a curved surface of a housing of an electronics device.

### Effect of Present Embodiment

As described above, in the present embodiment, the lead frame 10 is used as a substrate on which the solar cells 30 are to be provided. The use of the lead frame 10 allows the solar cells 30 to be connected with each other. In this arrangement, the solar cells 30 are connected with each other without using a conventional interconnector, thereby making it possible to provide a thin solar cell module 1. Further, ultimately, the upper surface of the lead frame 10 is covered with the transparent resin 60 and the lower surface of the lead frame 10 is covered with the insulating sheet 20, thereby reinforcing the solar cell module 1. As such, the solar cell module 1 in accordance with the present embodiment is thin and has sufficient mechanical strength, thereby resulting in that the solar cell module 1 can be provided in a portable electronics device.

### Second Embodiment

(Outline of Solar Cell Module 2)

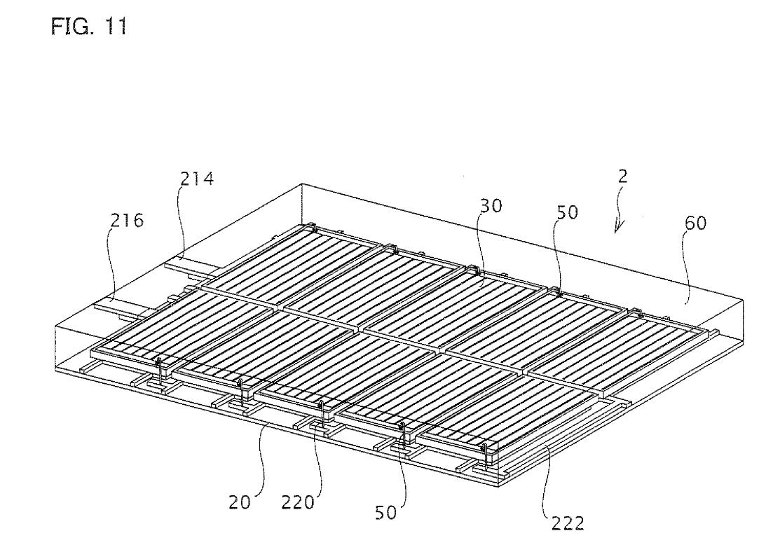

The following describes an outline of a solar cell module 2 in accordance with a second embodiment of the present invention with reference to FIGS. 11 to 13. The present embodiment is obtained by partially changing the first embodiment.

FIG. 11 is a perspective view of a whole solar cell module 2 in accordance with the present embodiment. The present embodiment is different from the first embodiment in that a cathode section 214 and an anode section 216 project from a side surface of the solar cell module 2, as shown in FIG. 11. In the first embodiment, the cathode section 114 and the anode section 116 are fixed to the lower surface of the solar cell module 1. However, in the present embodiment, projecting portions of the cathode section 214 and the anode section 216 can be folded toward any directions. On this account, in disposing the solar cell module 2 in a device, flexibility in how to connect the solar cell module 2 to the device increases. That is, the solar cell module 2 may be connected to the device by soldering, or alternatively by inserting the projecting portions into connectors.

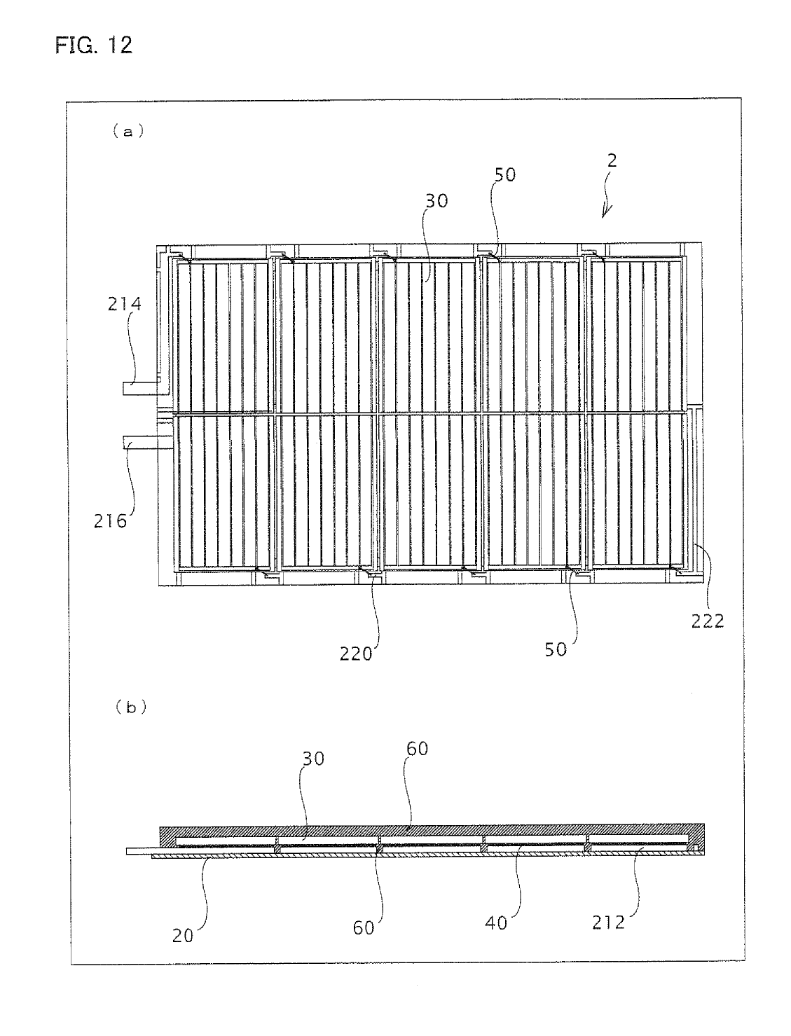

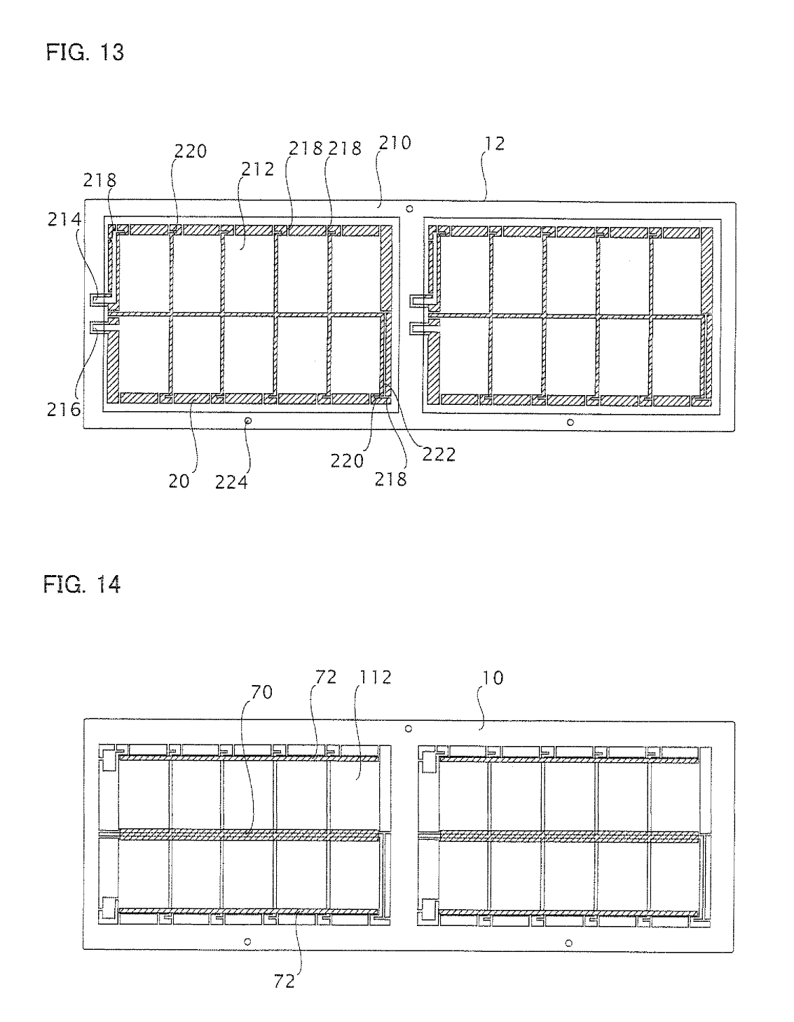

(a) of FIG. 12 shows an upper surface of the solar cell module 2 in accordance with the present embodiment, and (b) of FIG. 12 is a cross-sectional view of the solar cell module 2 in accordance with the present embodiment. As shown in FIG. 12, in the solar cell module 2, arrangements other than the above point are with the same as those in the first embodiment. FIG. 13 shows an upper surface of a lead frame 12 in accordance with the present embodiment. As shown in FIG. 13, a structure of the lead frame 12 is also the same as that of the first embodiment. In FIG. 13, a reference sign 210 indicates a cradle section, a reference sign 212 indicates a pad section, a reference sign 218 indicates a support bar, a reference sign 220 indicates an inner lead section, a reference sign 222 indicates a coupling section and a reference sign 224 indicates a hole. These sections function in the same manner as those described in the first embodiment.

### Third Embodiment

(Outline of Solar Cell Modules 1 and 2, Each of Which Includes Insulating Tapes 70 and 72 Attached Thereto)

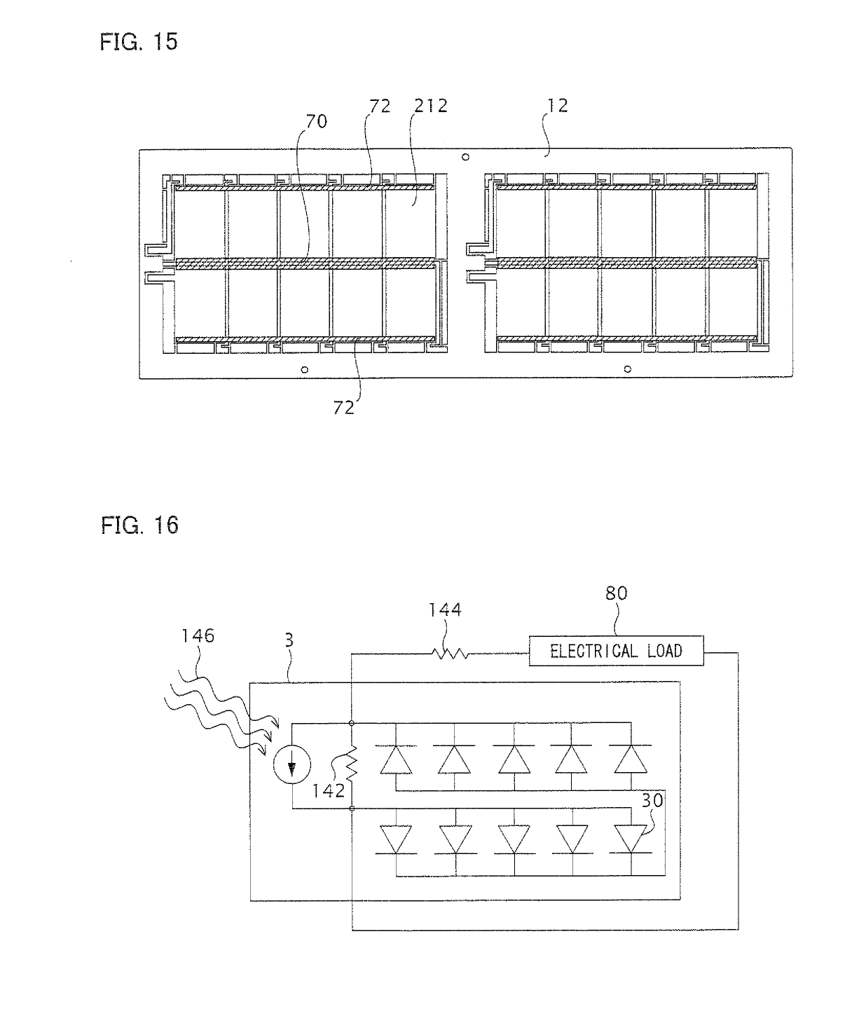

The following describes an outline of a solar cell module in accordance with a third embodiment of the present invention with reference to FIGS. 14 and 15. The first and second embodiments are renovated to obtain the present embodiment.

FIG. 14 shows an upper surface of a lead frame 10 on which insulating tapes 70 and 72 are attached. FIG. 15 shows an upper surface of a lead frame 12 on which the insulating tapes 70 and 72 are attached. In FIGS. 14 and 15, no insulating sheet 20 is provided on lower surfaces of the lead frames 10 and 12.

In the present embodiment, as shown in FIG. 14, the lead frame 10 in accordance with the first embodiment includes the insulating tapes 70 and 72 attached thereto. Similarly, as shown in FIG. 15, the lead frame 12 in accordance with the second embodiment includes the insulating tapes 70 and 72 attached thereto. The insulating tapes 70 and 72 are attached by an adhesive so as to cross pad sections. If the insulating tape 70 is not provided, only one side of the pad section (112, 212) is connected to the lead frame (10, 12). Attachment of the insulating tape 70 prevents the pad section (112, 212) from sagging by its own weight. Therefore, the insulating tape 70 functions as a reinforcing member for stable transportation in a manufacturing process. As with the insulating tape 70, the insulating tape 72 also functions as a reinforcing member. Making the insulating tapes 72 and 70 at same height prevents the solar cells 30 from leaning. A total thickness of each of the insulating tapes 70 and 72 ranges from 0.1 mm to 0.15 mm. Further, Kapton (registered trademark) or Upilex (registered trademark) is used for the insulating tapes 70 and 72.

The insulating sheet 20, if necessary, is provided on a lower surface of the lead frame (10, 12) after formation of a sheet 64 or individuation of the solar cell module (1, 2). In a case where the insulating sheet 20 is not provided, a surface of a tool which surface makes contact with the lower surface of the lead frame (10, 12) may be Teflon-coated. This can prevent leakage of the sheet 64.

### Fourth Embodiment

(Outline of Solar Cell Module 3)

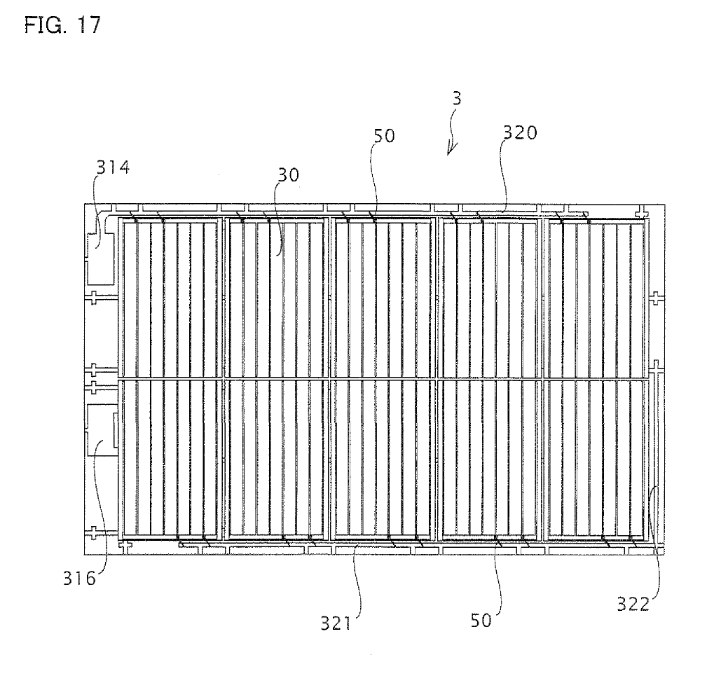

The following describes an outline of a solar cell module 3 in accordance with a fourth embodiment of the present invention with reference to FIGS. 16 and 17. The present embodiment is obtained by partially changing the first embodiment.

The present embodiment is different from the first embodiment in that the solar cells 30 are connected both in series and in parallel with each other. In the first embodiment, ten solar cells 30 are connected in series with each other. FIG. 16 shows an electric circuit of the solar cell module 3. In the present embodiment, as shown in FIG. 16, there are provided two sets of solar cells 30 each including five solar cells 30 that are connected in parallel with each other, and further the two sets of solar cells 30 are connected in series with each other. FIG. 17 shows an upper surface of a lead frame 14 in accordance with the present embodiment. As shown in FIG. 17, cathode sides of the upper five solar cells 30 are connected to an inner lead section 320 via gold wires 50 so that the cathode sides of the upper five solar cells 30 have the same electric potential as each other. On anode sides, pad sections 312 are connected with each other by coupling sections 324, therefore the anode sides of the upper five solar cells 30 have the same electric potential as each other. Hence, the upper five solar cells 30 are connected in parallel with each other. Similarly, cathode sides of the lower five solar cells 30 are connected to an inner lead 321 via the gold wires 50 so that the cathode sides of the lower five solar cells 30 have the same electric potential as each other. On anode sides, the pad sections 312 are connected with each other by the coupling sections 324, therefore the anode sides of the lower five solar cells 30 have the same electric potential as each other. Hence, the lower five solar cells 30 are also connected in parallel with each other. Further, a set of the upper solar cells 30 is connected in series with another set of the lower solar cells 30 by a coupling section 322.

This makes it possible that sets of the plurality of solar cells 30 that are connected in parallel with each other can be connected in series with each other, thereby realizing various configurations in which the solar cells 30 are connected with each other in different manners.

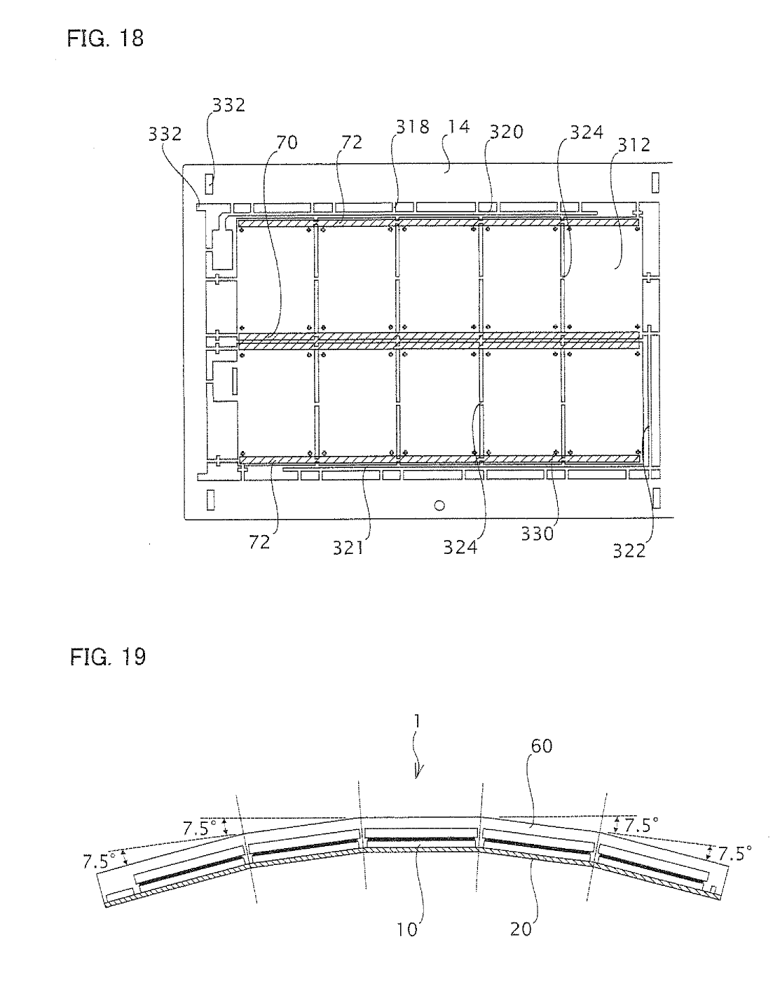

FIG. 18 shows an upper surface of the solar cell module 3 in accordance with the present embodiment. As shown in FIG. 18, cross dent portions 330 of the pad sections 312 are marks for arranging the solar cells 30 on the pad sections 312. Dent portions 332 of the lead frame 14 are marks for dividing the solar cell module 3 into individual pieces. It goes without saying that these marks are applicable to the first, second and third embodiments.

A reference sign 318 shown in FIG. 18 indicates a support bar and functions in the same manner as the support bar 118 described in the first embodiment.

### Fifth Embodiment

(Outline of Curved Solar Cell Modules 1, 2 and 3)

The following describes an embodiment in which any one of the solar cell modules 1, 2 and 3 of the present invention is used in a curved state with reference to FIG. 19. The following describes, for example, a case where the solar cell module 1 is used.

FIG. 19 is a cross-sectional view of the solar cell module 1 of the present invention which solar cell module 1 is in a curved state. In the present embodiment, as shown in FIG. 19, the solar cell module 1 is bended at four portions between the solar cells 30 adjacent to each other. An angle of each of the bended portions is 7.5°, and a total angle of the bended portions is 30°. The angle of each of the bended portions can be changed in accordance with a shape of a portion to which the solar cell module 1 is attached. The solar cell module 1 is curved by ductibility and plastic deformation of the lead frame 10 which is made from a metal. This can make the curve state steady while reducing elasticity of the solar cell module 1. For increasing the angle of the bended portions, intervals between the solar cells 30 are broadened.

In the present embodiment, the solar cell module 1 is curved so that the transparent resin 60 is outward. However, it is also possible to curve the solar cell module 1 so that the transparent resin 60 is inward. Further, in the present embodiment, the solar cell module 1 is bended at four portions. However, a certain portion to be bended may be selected as appropriate.

In the present embodiment, it is possible to curve the solar cell modules 1, 2 and 3 properly. This allows the flexibility of the solar cell module to increase. For example, any one of the solar cell modules 1, 2 and 3 can be disposed on a curved portion at the time of disposing the any one of the solar cell modules 1, 2 and 3 on a portable electronics device.

### Sixth Embodiment

(Outline of Mobile Phone 100)

The following describes an embodiment of a portable electronics device including the solar cell module 1, 2 or 3 of the present invention with reference to FIG. 20. The following describes, for example, a case where the solar cell module 1 is used.

(a) of FIG. 20 shows a side of a flip phone in an open state, which flip phone includes a solar cell module 1 in accordance with an embodiment of the present invention. (b) of FIG. 20 shows an upper surface of a flip phone in a closed state, which flip phone includes a solar cell module 1 in accordance with an embodiment of the present invention. (c) of FIG. 20 shows a side of a flip phone in a closed state, which flip phone includes a solar cell module 1 in accordance with an embodiment of the present invention. (d) of FIG. 20 shows a lower surface of a flip phone in a closed state, which flip phone includes a solar cell module 1 in accordance with an embodiment of the present invention.

As shown in (a) of FIG. 20, the mobile phone 100 of the present embodiment is a flip phone. A housing 201 including a key panel surface 101 is connected to a housing 202 including an information display surface 102 via a hinge section 104 so that the mobile phone 100 opens at a fixed angle. As shown in (b) of FIG. 20, a solar cell module 1 is attached to a surface of the housing 201 which surface is opposite to the key panel surface 101, and as shown in (d) of FIG. 20, another solar cell module 1 is also attached to a surface of the housing 202 which surface is opposite to the information display surface 102. On this account, as shown in (c) of FIG. 20, in a state where the mobile phone 100 is closed, the solar cell modules 1 are attached to both upper and lower surfaces of the mobile phone 100. In (b) of FIG. 20, a reference sign 106 indicates a camera lens and a reference sign 108 indicates a cover for a battery storage section.

The present embodiment discloses the flip phone 100, but the phone is not necessarily the flip phone 100. Further, the mobile phone 100 includes two solar cell modules 1, but it goes without saying that the phone can include one, or three or more solar cell modules 1.

The present embodiment can be applied to other portable electronics devices, such as a GPS (Global Positioning System) receiver, a desktop electronic dictionary, a digital still camera and a video camera. The present embodiment can be also applied to a remote controller of a television and the like.

### Overview of Embodiment

As described above, in order to attain the object, a solar cell module of the present invention includes a plurality of solar cells, comprises: a plurality of pad sections on each of which a corresponding one of the plurality of solar cells is provided such that the each of the plurality of pad sections is electrically connected to a first polar surface of the corresponding one of the plurality of solar cells; at least one inner lead section that is electrically connected to a second polar surface of at least one of the plurality of solar cells, the second polar surface having a polarity different from the first polar surface; a cathode section and an anode section, from which an electric current generated by each of the plurality of solar cells is fed; a lead frame made from a metal, in which lead frame the plurality of pad sections, the at least one inner lead section, the cathode section and the anode section are provided as a part of the lead frame itself; an insulating layer provided on a side of the lead frame which is opposite to another side of the lead frame on which the plurality of solar cells are provided; and a sealing layer for sealing at least the plurality of solar cells, the anode section and the cathode section, and it is preferable that the plurality of solar cells are connected with each other in such a manner that (i) all of the plurality of solar cells are connected with each other in series or in parallel, (ii) sets of solar cells, among the plurality of solar cells, are connected in parallel with each other and the sets of solar cells are connected in series with each other, or (iii) sets of solar cells, among the plurality of solar cells, are connected in series with each other and the sets of solar cells are connected in parallel with each other.

The configuration makes it possible to realize a solar cell module having various configurations in which the solar cells are connected with each other in different manners.

It is preferable to arrange the solar cell module of the present invention such that the anode section and the cathode section are exposed from the insulating layer.

The configuration makes it possible to feed an electric current from a lower surface of the lead frame of the solar cell module.

It is preferable to arrange the solar cell module of the present invention such that the cathode section and the anode section are provided so as to project from a side surface of the solar cell module.

In the above configuration, the cathode and anode sections of the lead frame project from the side surface of the solar cell module. This makes it possible to fold the projecting electrodes toward any directions. On this account, in disposing the solar cell module of the present invention in a device, flexibility in how to connect the solar cell module to the device increases. That is, the solar cell module of the present invention may be connected to the device by soldering, or alternatively by inserting the projecting electrodes into connectors.

It is preferable to arrange the solar cell module of the present invention such that the each of the plurality of pad sections is smaller in size than the corresponding one of the plurality of solar cells that is provided on the each of the plurality of pad sections.

In the above configuration, each of the pad sections provided in the lead frame is entirely covered with a corresponding solar cell. With the configuration, it is possible that a color of the lead frame is not viewed from an upper surface of the solar cell module ultimately, thereby improving an appearance of the solar cell module.

The solar cell module of the present invention is arranged such that a side of the each of the plurality of pad sections to which side the corresponding one of the plurality of solar cells is fixed is partially fixed by an insulating tape.

In the above configuration, the insulating tape is fixed to the pad sections provided on the lead frame. This prevents the pad sections from sagging by their own weight, and the insulating tape functions as a reinforcing member for stable transportation in a manufacturing process.

It is preferable to arrange the solar cell module of the present invention such that the each of the plurality of pad sections is connected to the corresponding one of the plurality of solar cells that is provided on the each of the plurality of pad sections, by a conductive material having a thermosetting property.

The configuration makes it possible to easily dispose each of the solar cells on a corresponding pad section.

It is preferable to arrange the solar cell module of the present invention such that the conductive material is a paste made by combining silver and a chemical product.

The configuration makes it possible to strongly and surely connect each of the solar cells to a corresponding pad section.

It is preferable to arrange the solar cell module of the present invention such that each of the plurality of solar cells is connected, by a metal wire, to a corresponding inner lead section.

The configuration makes it possible to surely connect each of the solar cells to the corresponding inner lead section.

It is preferable to arrange the solar cell module of the present invention such that the metal wire is a gold wire.

The configuration makes it possible to reduce electric resistance between each of the solar cells and the corresponding inner lead section.

It is preferable to arrange the solar cell module of the present invention such that a surface of the at least one inner lead section is coated with at least any one of gold, silver and tin.

The configuration makes it possible to stabilize connection of each of the solar cells and a corresponding inner lead section.

It is preferable to arrange the solar cell module of the present invention such that the sealing layer is made from any one of epoxy resin, ethylene vinyl acetate, and a laminated body of ethylene vinyl acetate and polyethylene terephthalate.

The solar cell module of the present invention is arranged such that the insulating layer is attached to a lower surface of the lead frame by an insulating adhesive.

It is preferable to arrange the solar cell module of the present invention such that the insulating layer is made from sheet-like polyimide or polyethylene terephthalate.

It is preferable to arrange the solar cell module of the present invention such that the each of the plurality of solar cells includes: an N⁺ layer, a P⁻ layer and a P⁺ layer, which are laminated in this order; a power collector-cum-cathode section formed by sintering silver on at least a part of an upper surface of the N⁺ layer; and an anode section formed by sintering aluminum on the P⁺ layer.

It is preferable to arrange the solar cell module of the present invention such that the solar cell module is bended at at least one portion between two solar cells adjacent to each other among the plurality of solar cells.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

A solar cell module of the present invention can be applied to portable electronics devices such as a mobile phone, a GPS (Global Positioning System) receiver, a desktop electronic dictionary, a digital still camera and a video camera. Further, the solar cell module of the present invention can be also applied to a remote controller of a television and the like.

### REFERENCE SIGNS LIST

1, 2 and 3 Solar Cell Module
10, 12 and 14 Lead Frame
20 Insulating Sheet
30 Solar Cell
40 Silver Paste
50 Gold Wire
60 Transparent Resin
62 EVA (ethylene vinyl acetate) Sheet
64 PET (polyethylene terephthalate) Sheet
66 Dent Portion
70 and 72 Insulating Tape
80 Cell
100 Mobile Phone
101 Key Panel Surface
102 Information Display Surface
104 Hinge Section
106 Camera Lens
108 Cover For Battery Storage Portion
110 and 210 Cradle Section
112, 212 and 312 Pad Section
112a Pad Section Adjacent To Anode Section 116
114, 214 and 314 Cathode Section
116, 216 and 316 Anode Section
118, 218 and 318 Support Bar
120, 220, 320 and 321 Inner Lead Section
122, 222 and 322 Coupling Section
124 and 224 Hole
130 P⁻ Layer
132 Power Collector
134 Portion That Collectively Includes Power Collectors
132
136 Aluminum Layer
138 N⁺ Layer
140 P⁺ Layer
142 Leakage Current Equivalent Resistance
144 Series Resistance
146 Light
201 Housing Including Key Panel Surface 101
202 Housing Including Information Display Surface 102
324 Coupling Section
330 Cross Dent Portion
332 Dent Portion Of Lead Frame

1. A solar cell module including a plurality of solar cells, comprising:
a plurality of pad sections on each of which a corresponding one of the plurality of solar cells is provided such that the each of the plurality of pad sections is electrically connected to a first polar surface of the corresponding one of the plurality of solar cells;
at least one inner lead section that is electrically connected to a second polar surface of at least one of the plurality of solar cells, the second polar surface having a polarity different from the first polar surface;
a cathode section and an anode section, from which an electric current generated by each of the plurality of solar cells is fed;
a lead frame made from a metal, in which lead frame the plurality of pad sections, the at least one inner lead section, the cathode section and the anode section are provided as a part of the lead frame itself;
an insulating layer provided on a side of the lead frame which is opposite to another side of the lead frame on which the plurality of solar cells are provided; and
a sealing layer for sealing at least the plurality of solar cells, the anode section and the cathode section.

2. The solar cell module as set forth in claim 1, wherein:
the plurality of solar cells are connected with each other in such a manner that (i) all of the plurality of solar cells are connected with each other in series or in parallel, (ii) sets of solar cells, among the plurality of solar cells, are connected in parallel with each other and the sets of solar cells are connected in series with each other, or (iii) sets of solar cells, among the plurality of solar cells, are connected in series with each other and the sets of solar cells are connected in parallel with each other.

3. The solar cell module as set forth in claim 1, wherein:
the anode section and the cathode section are exposed from the insulating layer.

4. The solar cell module as set forth in claim 1, wherein:
the cathode section and the anode section are provided so as to project from a side surface of the solar cell module.

5. The solar cell module as set forth in claim 1, wherein:
the each of the plurality of pad sections is smaller in size than the corresponding one of the plurality of solar cells that is provided on the each of the plurality of pad sections.

6. The solar cell module as set forth in claim 5, wherein:
a side of the each of the plurality of pad sections to which side the corresponding one of the plurality of solar cells is fixed is partially fixed by an insulating tape.

7. The solar cell module as set forth in claim 5, wherein:
the each of the plurality of pad sections is connected to the corresponding one of the plurality of solar cells that is provided on the each of the plurality of pad sections, by a conductive material having a thermosetting property.

8. The solar cell module as set forth in claim 7, wherein:
the conductive material is a paste made by combining silver and a chemical product.

9. The solar cell module as set forth in claim 2, wherein:
each of the plurality of solar cells is connected, by a metal wire, to a corresponding inner lead section.

10. The solar cell module as set forth in claim 9, wherein:
the metal wire is a gold wire.

11. The solar cell module as set forth in claim 9, wherein:
a surface of the at least one inner lead section is coated with at least any one of gold, silver and tin.

12. The solar cell module as set forth in claim 1, wherein:
the sealing layer is made from any one of epoxy resin, ethylene vinyl acetate, and a laminated body of ethylene vinyl acetate and polyethylene terephthalate.

13. The solar cell module as set forth in claim 1, wherein:
the insulating layer is attached to a lower surface of the lead frame by an insulating adhesive.

14. The solar cell module as set forth in claim 13, wherein:
the insulating layer is made from sheet-like polyimide or polyethylene terephthalate.

15. The solar cell module as set forth in claim 9, wherein:
the each of the plurality of solar cells includes:
an N⁺ layer, a P⁻ layer and a P⁺ layer, which are laminated in this order and whose base is silicon;
a power collector-cum-cathode section formed by sintering silver on at least a part of an upper surface of the N⁺ layer; and
an anode section formed by sintering aluminum on the P⁺ layer.

16. The solar cell module as set forth in claim 15, wherein:
the solar cell module is bended at at least one portion between two solar cells adjacent to each other among the plurality of solar cells.

17. A solar cell module including a plurality of solar cells, comprising:
a plurality of pad sections on each of which a corresponding one of the plurality of solar cells is provided;
at least one inner lead section that is electrically connected, via a metal wire, to the corresponding one of the plurality of solar cells;
a lead frame made from a metal which lead frame includes at least the plurality of pad sections and the at least one inner lead section;
an insulating layer provided on a side of the lead frame which is opposite to another side of the lead frame on which the plurality of solar cells are provided; and
a sealing layer for sealing the plurality of solar cells and the metal wire,
the solar cell module being capable of being disposed on a housing of an electronics device with the solar cell module curved.

18. A method for producing a solar cell module including a plurality of solar cells, comprising the steps of:
preparing a lead frame made from a metal by forming, in the lead frame, a plurality of pad sections, an inner lead section, an anode section and a cathode section as a part of the lead frame itself;
disposing a conductive material having a thermosetting property on each of the plurality of pad sections;
disposing a corresponding one of the plurality of solar cells on the each of the plurality of pad sections on which the conductive material is disposed, the corresponding one of the plurality of solar cells being disposed in such a manner that a first polar surface of the corresponding one of the plurality of the solar cells faces the each of the plurality of pad sections;
hardening the conductive material by heating the lead frame on which the plurality of solar cells are disposed;
connecting a second polar surface of the each of the plurality of solar cells to the inner lead section via a metal wire, the second polar surface having a polarity different from the first polar surface;
forming an insulating layer provided on a side of the lead frame which is opposite to another side of the lead frame on which the plurality of solar cells are provided; and
forming a scaling layer so as to seal at least the plurality of solar cells, the anode section and the cathode section.

19. An electronics device comprising a solar cell module as set forth in claim 1.
